(19) United States
(12) Patent Application Publication
(10) Pub. No.: US 2006/0151787 A1
(43) Pub. Date: Jul. 13, 2006

(54) LOW CONCENTRATION SiGe BUFFER DURING STRAINED Si GROWTH OF SSGOI MATERIAL FOR DOPANT DIFFUSION CONTROL AND DEFECT REDUCTION

(75) Inventors: Huajie Chen, Danbury, CT (US); Anda C. Mocuta, LaGrangeville, NY (US); Stephen W. Bedell, Wappingers Falls, NY (US); Effendi Leobandung, Wappingers Falls, NY (US); Devendra K. Sadana, Pleasantville, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 10/905,595

(22) Filed: Jan. 12, 2005

(51) Int. Cl. H01L 29/12; H01L 21/20

(52) U.S. Cl. 257/65; 438/478; 438/763; 257/616

(57) ABSTRACT

A method and structure for fabricating a strained semiconductor on a relaxed SiGe substrate which has dopant diffusion control and defect reduction are provided. Specifically, the dopant diffusion control and defect reduction is achieved in the present invention by providing a SiGe buffer layer between the strained semiconductor and the underlying relaxed SiGe substrate. In accordance with the present invention, the SiGe buffer layer has a Ge content that is less than the Ge content which is present in the relaxed SiGe substrate.

### FIELD OF THE INVENTION

The present invention relates to semiconductor materials that include a strained semiconductor located atop a substrate that includes an upper relaxed SiGe alloy layer as well as a method of fabricating the same. In particular, the present invention relates to a strained Si/SiGe-on-insulator (SSGOI) material, in which the strained Si is located on a SiGe buffer layer having a lower Ge content than an underlying relaxed SiGe substrate.

### BACKGROUND OF THE INVENTION

Improvements in transport properties, i.e., carrier mobility, through strain have been demonstrated in the operating characteristics of field effect transistors (FETs). For complementary metal oxide semiconductor (CMOS) devices, an improvement in device characteristics through enhanced mobility has significant potential for the fabrication of very high-speed devices. Strained silicon on a relaxed SiGe substrate is one system where such an improvement occurs. See, for example, K. Rim, et al., “Fabrication and analysis of deep submicron strained-Si n-MOSFET's”, IEEE Trans. Electron Devices, Vol. 47, pp. 1406-1415 (2000).

Experimental research on enhanced carrier mobility metal oxide semiconductor field effect transistors (MOSFETs) caused by strain has concentrated on a strained Si layer grown on a relaxed SiGe substrate, on a bulk substrate or SOI. Strained Si on an SOI substrate was developed to gain benefits of both strained Si and SOI. In such technology, an initial substrate 10 (see FIG. 1) including a relaxed or partially relaxed SiGe alloy layer 16 located atop a buried insulator layer 14 that is positioned on a Si-containing substrate 12 is first provided. The initial substrate 10 can be formed by a layer transfer process, oxygen implantation or by a thermal mixing process in which a thick strained SiGe layer is formed atop a silicon-on-insulator (SOI) and thereafter the structure is subjected to an anneal step which causes strain relaxation of the SiGe layer by way of defect formation. A strained Si layer 18 can then be formed atop the relaxed or partially relaxed SiGe layer 16 providing the structure shown in FIG. 2. In a typical prior art strained Si/silicon germanium-on-insulator (SSGOI) structure, a 200 Å strained Si layer is formed atop a 400 Å SiGe layer that has a measured relaxation value from about 50 to about 70% and a Ge content of about 26%. Devices formed on such a prior art SSGOI structure show improved performance. For example, up to 80-90% enhancement of mobility and 20-25% Ion improvement has been observed for nFET devices, as published by B. Lee, et al., “Performance enhancement on sub-70 nm strained silicon SOI MOSFETs on ultra-thin thermally mixed strained silicon/SiGe on insulator (TM-SGOI) substrate with raised S/D”, IEDM Tech. Digest, pp. 946-948 (2002).

Despite the above performance improvements, it has been observed that devices formed on such an SSGOI substrate as shown in FIG. 2 are highly sensitive to the Ge fraction, due to enhanced dopant diffusion in SiGe. In particular and in such structures, the overlap capacitance, Cₒᵥ, is highly sensitive to the Ge fraction of the SiGe layer.

Moreover, the threshold voltage roll-off for nFETs is also highly sensitive to the Ge fraction within the SiGe alloy layer. The term “threshold voltage roll-off” denotes the different device threshold voltages that can exist within a system or chip caused by process variations that effect the channel length of each transistor.

The above problems can be solved by growing a thicker Si layer or by reducing the Ge content within the strain relaxed SiGe layer. However, Si thickness is limited by the critical thickness of the film, beyond which the strained Si film will begin to relax and defects will be generated in the film. Reducing Ge content generally leads to lower strain in the overlaying Si layer, reducing the performance enhancement. Therefore, a method is needed that can keep the strain and thickness of the overlaying Si layer the same, while reducing the Ge fraction in the SiGe alloy layer.

U.S. Pat. No. 6,703,688 to Fitzergald describes relaxed SiGe platforms for high-speed CMOS electronics and high-speed analog circuits. Specifically, the '688 patent uses thick graded SiGe to produce relaxed SiGe, then a CMP process is used to smooth the surface. SiGe is then regrown on the smoothed relaxed SiGe and thereafter a strained Si layer is formed atop the regrown SiGe. Because the regrown SiGe is typically on the order of 0.5 μm or more, it's critical that the regrown SiGe is within less than 0.04% lattice matched to the relaxed SiGe. However, since the relaxed SiGe with the thick graded SiGe approach described in the '688 patent is typically close to 100% relaxed, the regrown SiGe has a Ge content that is about equal to that of the underlying SiGe layer. Because the content of Ge is approximately equal in the smoothed SiGe layer and the regrown SiGe layer, the structure disclosed in the '688 patent would exhibit much enhanced diffusion of dopants such as As which increases the sensitivity of the resultant device.

### SUMMARY OF THE INVENTION

The present invention provides a method and structure for fabricating a strained semiconductor on a relaxed SiGe substrate which has dopant diffusion control and defect reduction. Specifically, the dopant diffusion control and defect reduction are achieved in the present invention by providing a SiGe buffer layer between the strained semiconductor and the underlying relaxed SiGe substrate. In accordance with the present invention, the SiGe buffer layer has a Ge content that is less than the Ge content which is present in the relaxed SiGe substrate.

In broad terms, the present invention provides a semiconductor material which comprises:

a relaxed SiGe substrate having a first Ge content;

a SiGe buffer layer located atop said relaxed SiGe substrate, said SiGe buffer layer having a second Ge content which is less than the first Ge content; and

a strained semiconductor located atop said SiGe buffer layer.

The semiconductor material described above can be used as a substrate for forming one or more CMOS devices such as FETs thereon. In accordance with the present invention, a semiconductor structure is thus provided that comprises:

a relaxed SiGe substrate having a first Ge content;

a SiGe buffer layer located atop said relaxed SiGe substrate, said SiGe buffer layer having a second Ge content which is less than the first Ge content;

a strained semiconductor located atop said SiGe buffer layer; and

one or more complementary metal oxide semiconductor (CMOS) devices located on said strained semiconductor, wherein a portion of said strained semiconductor serves as a channel for said one or more CMOS devices.

The present invention also provides a method of fabricating the semiconductor material described above. Specifically, the method of the present invention comprises the steps of:

providing a relaxed SiGe substrate having a first Ge content and a first thickness;

forming a SiGe buffer layer having a second Ge content and a second thickness, wherein said second Ge content is less than the first Ge content; and

forming a strained semiconductor atop the SiGe buffer layer.

The method of the present invention can be easily integrated into a CMOS process flow wherein one or more CMOS devices, such as FETs, are formed atop the strained semiconductor.

### BRIEF DESCRIPTION OF THE DRAWINGS

FIG. 1 is a pictorial representation (through a cross sectional view) illustrating a prior art relaxed SiGe substrate.

FIG. 2 is a pictorial representation (through a cross sectional view) illustrating the relaxed SiGe substrate of FIG. 1 after a strained semiconductor is formed thereon.

FIGS. 3A-3C are pictorial representations (through cross sectional views) illustrating the basic processing steps that are employed in the present invention for fabricating a semiconductor material that has dopant diffusion control and defect reduction.

FIG. 4 is a pictorial representation (through a cross sectional view) illustrating the semiconductor material shown in FIG. 3C after a FET is formed thereon.

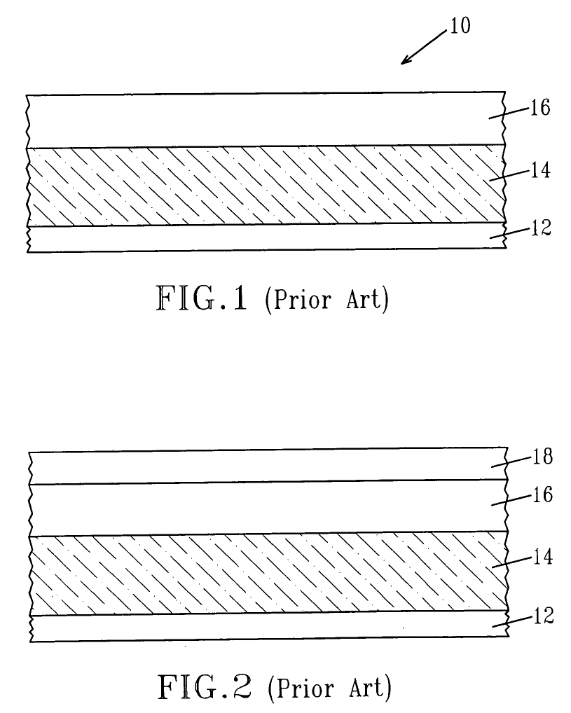

### DETAILED DESCRIPTION OF THE INVENTION

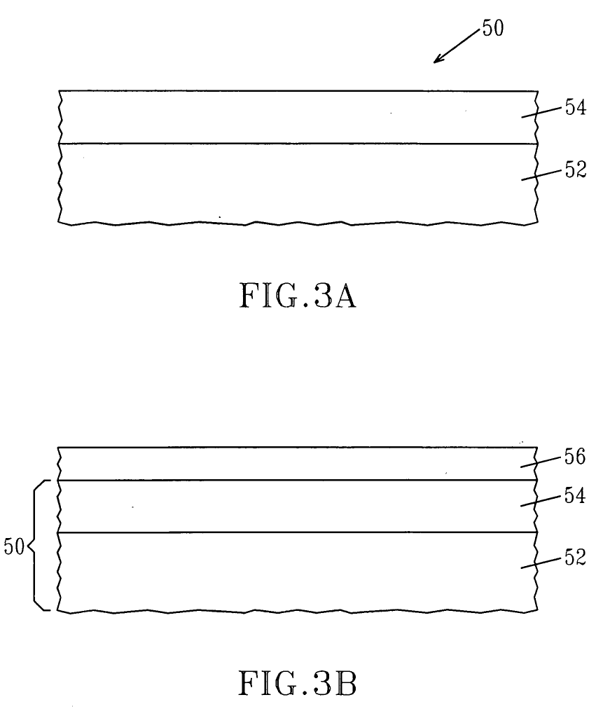

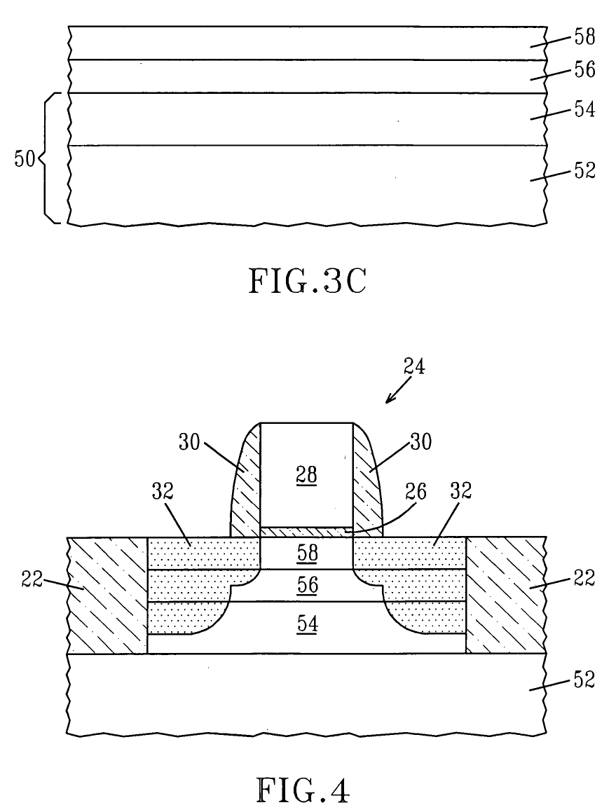

The present invention, which provides a semiconductor material including a strained semiconductor located atop a relaxed SiGe substrate having dopant diffusion control and defect reduction as well as a method of fabricating the same, will now be described in greater detail by referring to the drawings that accompany the present application. It is noted that the drawings of the present invention are provided for illustrative purposes only and thus they are not drawn to scale. Moreover, the drawings illustrated in FIGS. 3A-3C and FIG. 4 show an embodiment of the present invention in which blanket layers are formed. Although this embodiment is shown, the present invention also contemplates forming a semiconductor material which includes patterned layers, i.e., patterned strained semiconductor on a patterned or unpatterned SiGe buffer, which, in turn is formed on a patterned or unpatterned relaxed SiGe substrate.

Reference is first made to FIG. 3A which illustrates an initial relaxed SiGe substrate 50 that can be used in the present invention. The initial relaxed SiGe substrate 50 comprises a substrate 52 and a relaxed SiGe layer 54. The substrate 52 can be a bulk semiconductor material such as Si, Ge, SiGe, SiC, SiGeC, InAs, InP or another III/V or Il/VI compound semiconductors. The substrate 52 can also comprise a silicon-on-insulator (SOI), a silicon germanium-on-insulator (SGOI) or a layered semiconductor such as Si/SiGe. In some embodiments, substrate 52 includes a portion of a SOI or SGOI substrate; in particular, substrate 52 could include a buried insulating layer that is typically resistant to Ge diffusion such as a buried oxide, nitride, or oxynitride located atop a semiconductor material.

In one preferred embodiment of the present invention, the substrate 52 is a Si-containing semiconductor such as Si, SiGe, SiC, SiGeC, SOI or SGOI. In another preferred embodiment, the substrate 52 comprises a buried insulating layer located atop a Si-containing semiconductor.

The relaxed SiGe layer 54 of the substrate 52 includes a SiGe alloy layer having a first Ge content and a first thickness. Specifically, the relaxed SiGe alloy 54 has a first Ge content of about 20 atomic % or greater, with a first Ge content from about 25 atomic % or greater being more typical. As stated above, when formed on an insulating layer, the relaxed SiGe layer 54 has a first thickness that is typically from about 100 to about 1000 Å, with a first thickness from about 200 to about 500 Å being even more typical. When formed on top of a bulk substrate, the relaxed SiGe layer 54 has a first thickness that is typically from about 1000 Å to about 3 μm, with a first thickness from about 0.5 to about 2 μm being even more typical. Another characteristic feature of the relaxed SiGe layer 54 is that it has a measured degree of relaxation that is typically from about 40% or greater, with a measured relaxation from about 50% or greater being even more typical.

The relaxed SiGe layer 54 may have a uniform Ge content incorporated throughout the entire layer, or the relaxed SiGe layer 54 may have a graded Ge content that varies throughout the layer.

In one embodiment of the present invention, the relaxed SiGe substrate 50 can be formed by utilizing a thermal mixing process such as described, for example, in co-assigned U.S. application Ser. No. 10/055,138, filed Jan. 23, 2002, entitled “Method of Creating High-Quality Relaxed SiGe-on-Insulator for Strained Si CMOS Applications”, now U.S. Pat. No. 6,805,962, and Ser. No. 10/448,947, filed May 30, 2003, entitled “Formation of Silicon-Germanium-on-Insulator (SGOI) by an Integral High Temperature SIMOX-Ge Interdiffusion Anneal”, the entire contents of each of the aforementioned applications are incorporated herein by reference.

The thermal annealing process typically includes growing a thick strained SiGe layer atop a silicon-on-insulator (SOI) and thereafter the structure is subjected to an anneal step in an oxidizing environment which causes strain relaxation of the SiGe layer by way of defect formation, or by implanting ions into a Si-containing substrate, forming a Ge-containing layer on the Si-containing substrate containing said implanted ions, and annealing which causes interdiffusion of Ge and the formation of a relaxed SiGe layer atop a buried insulating layer.

In addition to thermal mixing, the relaxed SiGe substrate 50 can be formed by a layer transfer process in which a thermal bonding step is employed. The layered transfer process includes the use of a first wafer that contains a SiGe layer atop a handle wafer and a second wafer that includes a semiconductor substrate, with or without a surface dielectric layer. In accordance with a typical layer transfer process, the two wafers are brought into intimate contact with each such that a surface of the SiGe layer is in contact with the second wafer and then the contacted wafers are heated to cause bonding between the two wafers. A portion of the first wafer including at least the handle wafer is then removed by chemical mechanical polishing (CMP) or another like process. In some instances, the handle wafer can include a hydrogen implant region which can be used to remove portions of the handle wafer from the bonded structure.

In yet another embodiment of the present invention, it is possible to grow the relaxed SiGe layer 54 on a surface of the substrate 52 utilizing any conventional epitaxial growth method that is known to those skilled in the art that is capable of growing a SiGe layer that is relaxed. Illustrative examples of such epitaxial growth processes that can be used to grown the relaxed SiGe layer include, but are not limited to: low-pressure chemical vapor deposition (LPCVD), rapid thermal chemical vapor deposition (RTCVD), low-energy plasma deposition (LEPD), ultra-high vacuum chemical vapor deposition (UHVCVD), atmospheric pressure chemical vapor deposition (APCVD), molecular beam epitaxy (MBE), or plasma-enhanced chemical vapor deposition (PECVD).

In yet another embodiment of the present invention, the relaxed SiGe substrate 50 can be formed by oxidation of a buried porous silicon layer such as is described, for example, in co-assigned U.S. application Ser. No. 10/662,028, filed Sep. 12, 2003, entitled “Formation of Silicon Germanium-on-Insulator Structure By Oxidation of a Buried Porous Silicon Layer”, the entire content of which is incorporated herein by reference. In such a process, the relaxed SiGe layer is formed by providing a structure that includes a Si-containing layer having a hole-rich region located therein and a Ge-containing layer atop the substrate, converting the hole-rich region into a porous region via an electrolytic anodization process, and annealing.

In addition to the above described embodiment, the present invention also contemplates an embodiment in which a relaxed SiGe is formed on a bulk substrate. When this embodiment is employed, the following processing steps can be performed: epitaxially grow a thick relaxed SiGe layer on a bulk substrate, planarizing the thick relaxed SiGe layer by chemical mechanical polishing or another like planarization process, and regrowing the SiGe by epitaxy. In addition to the above processing steps, a relaxed SiGe layer can be formed atop a bulk substrate by epitaxially growing a strained SiGe layer on a bulk substrate, implanting He into the structure, annealing to relax the stained SiGe layer, and SiGe regrowth.

After providing the structure shown in FIG. 3A, a SiGe buffer layer 56 having a second Ge content and a second thickness is formed atop the relaxed SiGe substrate 50. The structure including the SiGe buffer layer 56 is shown in FIG. 3B. In accordance with the present invention, the SiGe buffer layer 56 has a second Ge content and a second thickness, with the second Ge content less than the first Ge content of the relaxed SiGe layer 54. The SiGe buffer layer 56 is formed utilizing one of the epitaxial growth methods mentioned hereinabove. Thus, for example, the SiGe buffer layer 56 can be formed by LPCVD, RTCVD, LEPD, UHVCVD, APCVD, MBE, or PECVD.

As stated above, the SiGe buffer layer 56 has a second Ge content that is less than that of the first Ge content. Typically, the SiGe buffer layer 56 has a Ge content that is less than the Ge content present in the relaxed SiGe layer 54 by at least 5 atomic %. Thus, the second Ge content with the SiGe buffer layer 56 is about 20 atomic % or less, with a Ge content of 15 atomic percent or less being even more typical. The second thickness of the SiGe buffer layer 56 is typically from about 50 to about 400 Å, with a second thickness from about 100 about 200 Å being even more typical. The SiGe buffer layer 56 may have a uniform Ge content distributed throughout the entire layer, or it may comprise a SiGe layer having a graded Ge content.

In accordance with the present invention, the SiGe buffer layer 56 is typically latticed matched to the underlying relaxed SiGe layer 54 when it's formed on SGOI. Hence, the SiGe buffer layer 56 may be completely unstrained or, depending on the degree of relaxation of the relaxed SiGe layer 54, it may have some strain associated therewith. In cases in which the SiGe buffer layer 56 does not have any strain associated therewith, its thickness is not limited to a critical thickness value.

Because the SiGe buffer layer 56 has a lower content of Ge than the underlying SiGe layer 54, the N type dopant diffusion through the layer is greatly minimized.

Next, and as shown in FIG. 3C, a strained semiconductor 58 is formed atop the SiGe buffer layer 56. Examples of strained semiconductor material that can be formed atop the SiGe buffer layer 56 include strained Si, strained SiGe, strained SiC, strained SiGeC, and other like semiconductor materials. In some embodiments, the strained semiconductor is a strained Si layer. The strained semiconductor 58 can be formed utilizing the same or different epitaxial growth process as was used previously to form the SiGe buffer layer 56. Preferably, the strained semiconductor 58 is formed utilizing the same epitaxy growth process as used to form the SiGe buffer 56. In this embodiment, the deposition of layers 58 and 56 can occur within the same reactor chamber without breaking vacuum between the deposition steps.

The thickness of the strained semiconductor 58 formed at this point of the present invention may vary depending on the type of semiconductor material employed as well as the technique that was used to deposit the same. Typically, the strained semiconductor 58 has a thickness from about 20 to about 400 Å, with a thickness from about 50 to about 200 Å being even more typical.

It addition to substantially reducing N type dopant diffusion, the SiGe buffer layer 56 also reduces the defects that are formed in the strained semiconductor 58. For example, in one experiment, when a SiGe buffer layer 56 is grown on the relaxed SiGe layer 54 which has some defects present therein, with less optimized hydrogen prebake process that doesn't fully remove the surface oxygen, the SiGe buffer layer 56 reduces etch defects in the strained semiconductor 58 (Si) from 2.3E7 defects/cm² to 8E6 defects/cm². In another experiment, when grown on a pseudomorphic defect free SiGe layer, a 4E6 defects/cm² etch defect was observed in the strained Si without the SiGe buffer layer, compared to a less than 1E4 defect/cm² etch defect that was observed in the strained Si with the SiGe buffer layer.

The semiconductor material shown in FIG. 3C, including the relaxed SiGe substrate 50, the SiGe buffer layer 56, and the strained semiconductor 58 can be used as a substrate in which at least one or more CMOS devices, including, for example, FETs, can be formed. The inventive semiconductor material is most beneficial to nFETs since it will provide sharper nFET extensions to those devices. The inventive semiconductor material also makes device design easier and it also alleviates silicide formation problem that is typically exhibited when a SiGe layer having a high content of Ge is employed directly beneath the strained semiconductor layer.

FIG. 4 shows the semiconductor material of FIG. 3C after trench isolation regions 22 and at least one CMOS device 24 is formed atop the strained semiconductor 58. The at least one CMOS device 24 includes a gate dielectric 26, a gate conductor 28, spacer 30, and source/drain regions 32.

The trench isolation regions 22 are typically formed prior to forming the at least one CMOS device 24. Specifically, the trench isolation regions 22 are formed utilizing a conventional trench isolation process which includes, providing a trench into the semiconductor material shown in FIG. 3C by lithography and etching, optionally lining the trench with a trench liner material, filling the trench with a trench dielectric material, and, if needed, planarizing the structure. The trench dielectric material includes a dielectric material such as a high-density oxide or tetraethylorthosilicate. An optional densification step can be also be used. In embodiments in which a buried insulating layer is present beneath the relaxed SiGe layer 54, the trench isolation regions 22 can extend to the upper surface of the buried insulating layer or they can extend to the underlying semiconductor material that is beneath the buried insulating layer.

A gate dielectric 26 is formed on the entire surface of the structure including the strained semiconductor 58 and atop the trench isolation regions 22, if it is a deposited dielectric. The gate dielectric 26 can be formed by a thermal growing process such as, for example, oxidation, nitridation or oxynitridation. Alternatively, the gate dielectric 26 can be formed by a deposition process such as, for example, chemical vapor deposition (CVD), plasma-assisted CVD, atomic layer deposition (ALD), evaporation, reactive sputtering, chemical solution deposition or other like deposition processes. The gate dielectric 26 may also be formed utilizing any combination of the above processes.

The gate dielectric 26 is comprised of an insulating material including, but not limited to: an oxide, nitride, oxynitride, a high k dielectric (k greater than 4.0, typically greater than 7.0) and/or a silicate. In one embodiment, it is preferred that the gate dielectric 26 is comprised of an oxide such as, for example, SiO₂, HfO₂, ZrO₂, Al₂O₃, TiO₂, La₂O₃, SrTiO₃, LaAlO₃ or mixtures thereof.

The physical thickness of the gate dielectric 26 may vary, but typically, the gate dielectric 26 has a thickness from about 0.5 to about 10 nm, with a thickness from about 0.5 to about 3 nm being more typical.

After forming the gate dielectric 26, a blanket layer of polysilicon or another gate conductor material or combination thereof, which becomes the gate conductor 28, is formed on the gate dielectric 26 utilizing a known deposition process such as, for example, physical vapor deposition, CVD or evaporation. The blanket layer of gate conductor material may be doped or undoped. If doped, an in-situ doping deposition process may be employed in forming the same. Alternatively, a doped gate conductor layer can be formed by deposition, ion implantation and annealing. The doping of the gate conductor layer will shift the workfunction of the gate formed. Illustrative examples of dopant ions include As, P, B, Sb, Bi, In, Al, Ga, TI or mixtures thereof. Typical doses for the ion implants are 1 E14 (=1×10¹⁴) to 1 E16 (=1×10¹⁶) atoms/cm² or more typically 1 E15 to 5E15 atoms/cm². The thickness, i.e., height, of the gate conductor layer deposited at this point of the present invention may vary depending on the deposition process employed. Typically, the gate conductor layer has a vertical thickness from about 20 to about 180 nm, with a thickness from about 40 to about 150 nm being more typical.

The gate conductor 28 can comprise any conductive material that is typically employed as a gate of a CMOS structure. Illustrative examples of such conductive materials that can be employed as the gate conductor 28 include, but are not limited to: polysilicon, metals or metal alloys, silicides, conductive nitrides, polySiGe and combinations thereof, including multilayers thereof. In some embodiments, it is possible to form a barrier layer between multiple layers of gate conductors.

An optional dielectric cap (not shown) can be formed atop the gate conductor 28 at this point of the present invention. The optional dielectric cap is typically removed before or immediately after the source/drain regions have been silicided.

The blanket gate conductor 28 is then patterned by lithography and etching so as to provide patterned gate stacks. The patterned gate stacks may have the same dimension, i.e., length, or they can have variable dimensions to improve device performance. Each patterned gate stack at this point of the present invention includes at least the gate conductor 28. The lithography step includes applying a photoresist to the upper surface of the gate conductor 28, exposing the photoresist to a desired pattern of radiation and developing the exposed photoresist utilizing a conventional resist developer. The pattern in the photoresist is then transferred to the blanket layer of gate conductor 28 utilizing one or more dry etching steps. In some embodiments, the patterned photoresist may be removed after the pattern has been transferred into the blanket layer of gate conductor 28.

Suitable dry etching processes that can be used in the present invention in forming the patterned gate stacks include, but are not limited to: reactive ion etching, ion beam etching, plasma etching or laser ablation. The dry etching process employed is typically selective to the underlying gate dielectric 26 therefore this etching step does not typically remove the gate dielectric. In some embodiments, this etching step may however be used to remove portions of the gate dielectric 26 that are not protected by the gate stacks. A wet etching process can also be used to remove portions of the gate dielectric 26 that are not protected by the gate stacks.

In the present invention, a portion of the strained semiconductor 58 beneath the gate conductor 28 serves as the channel region of the CMOS devices.

At least one spacer 30 is formed on exposed sidewalls of each patterned gate stack. The at least one spacer 30 is comprised of an insulator such as an oxide, nitride, oxynitride and/or any combination thereof. Preferably, oxide inner spacers are formed and nitride outer spacers are formed. The at least one spacer 30 is formed by deposition and etching.

The width of the at least one spacer 30 must be sufficiently wide enough such that the source and drain silicide contacts (to be subsequently formed) do not encroach underneath the edges of the gate stack. Typically, the source/drain silicide does not encroach underneath the edges of the gate stack when the at least one spacer has a width, as measured at the bottom, from about 15 to about 80 nm.

After spacer formation, source/drain diffusion regions 32 are formed into at least the strained semiconductor 58 and SiGe buffer layer 56 utilizing ion implantation and an annealing step. The annealing step serves to activate the dopants that were implanted by the previous implant step. The conditions for the ion implantation and annealing are well known to those skilled in the art. In the present invention, the phrase “source/drain diffusion regions” includes extension regions, halo regions and deep source/drain regions (extension implant is usually done before the final spacer formation). The extension region of NFETs is limited to layer 58 and 56, so that NFET extension diffusion is controlled. When the FET is built on SGOI, the S/D is typically extended all the way to the buried insulator layer, to minimize junction capacitance.

In some embodiments of the present invention and when the strained semiconductor 58 does not include silicon, a Si-containing layer can be formed atop portions of layer 58 to provide a source for forming the silicide contacts. Illustrative examples of Si-containing materials that can be used include, for example, Si, single crystal Si, polycrystalline Si, SiGe, and amorphous Si. This embodiment of the present invention is not illustrated in the drawings.

Next, the top of the source/drain diffusion regions 32 are silicided utilizing a standard salicidation process well known in the art. This step, which is not shown in the drawings, includes forming a metal capable of reacting with Si atop the entire structure, forming an oxygen barrier layer atop the metal, heating the structure to form a silicide, removing non-reacted metal and the oxygen barrier layer and, if needed, conducting a second heating step. The second heating step is required in those instances in which the first heating step does not form the lowest resistance phase of the silicide. Note that if the gate conductor 28 is comprised of polysilicon or SiGe, this step of the present invention can be used in forming a metal suicide atop the Si-containing gate conductor.

After silicidation of the at least the source/drain regions 32, the structure can be subjected to a conventional back-end-of-the-line process in which a dielectric material including conductively filled contact vias are formed which extend to the silicided source/drain regions.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor material comprising:
a relaxed SiGe substrate having a first Ge content;
a SiGe buffer layer located atop said relaxed SiGe substrate, said SiGe buffer layer having a second Ge content which is less than the first Ge content; and
a strained semiconductor located atop said SiGe buffer layer.

2. The semiconductor material of claim 1 wherein said relaxed SiGe substrate includes a relaxed SiGe layer located atop a semiconductor substrate.

3. The semiconductor material of claim 2 wherein said semiconductor substrate comprises a buried insulating layer atop a semiconductor material.

4. The semiconductor material of claim 1 wherein said relaxed SiGe substrate includes a SiGe layer having a measured relaxation of about 40% or greater.

5. The semiconductor material of claim 1 wherein said first Ge content is about 20 atomic % or greater.

6. The semiconductor material of claim 1 wherein said second Ge content is less than the first Ge content by at least 5 atomic %.

7. The semiconductor material of claim 1 wherein strained semiconductor comprises Si.

8. A semiconductor structure comprising:
a relaxed SiGe substrate having a first Ge content;
a SiGe buffer layer located atop said relaxed SiGe substrate, said SiGe buffer layer having a second Ge content which is less than the first Ge content;
a strained semiconductor located atop said SiGe buffer layer; and
one or more complementary metal oxide semiconductor (CMOS) devices located on said strained semiconductor, wherein a portion of said strained semiconductor serves as a channel for said one or more CMOS devices.

9. The semiconductor structure of claim 8 further comprising at least one trench isolation region.

10. A method of fabricating a semiconductor material comprising the steps of:
providing a relaxed SiGe substrate having a first Ge content and a first thickness;
forming a SiGe buffer layer having a second Ge content and a second thickness, wherein said second Ge content is less than the first Ge content; and
forming a strained semiconductor atop the SiGe buffer layer.

11. The method of claim 10 wherein said providing said relaxed SiGe substrate comprises a thermal mixing process, a layer transfer process, epitaxial growth on a semiconductor substrate, or anodization process.

12. The method of claim 10 wherein said forming said SiGe buffer layer comprises an epitaxial growth process selected from the group consisting of low-pressure chemical vapor deposition (LPCVD), rapid thermal chemical vapor deposition (RTCVD), low-energy plasma deposition (LEPD), ultra-high vacuum chemical vapor deposition (UHVCVD), atmospheric pressure chemical vapor deposition (APCVD), molecular beam epitaxy (MBE) and plasma-enhanced chemical vapor deposition (PECVD).

13. The method of claim 10 wherein first Ge content is about 20 atomic percent or greater and said second Ge content is about 15 atomic percent or less.

14. The method of claim 10 wherein said first thickness is from about 100 to about 1000 Å, and said second thickness is from about 50 to about 400 Å.

15. The method of claim 10 wherein said SiGe buffer layer and said strained semiconductor are formed in a same reactor chamber without breaking vacuum.

16. The method of claim 10 wherein said forming said strained semiconductor layer comprises an epitaxial growth process selected from the group consisting of low-pressure chemical vapor deposition (LPCVD), rapid thermal chemical vapor deposition (RTCVD), low-energy plasma deposition (LEPD), ultra-high vacuum chemical vapor deposition (UHVCVD), atmospheric pressure chemical vapor deposition (APCVD), molecular beam epitaxy (MBE) and plasma-enhanced chemical vapor deposition (PECVD).

17. The method of claim 10 further comprising forming at least one complementary metal oxide semiconductor device on said strained semiconductor.

18. The method of claim 10 wherein said strained semiconductor comprises Si.

19. The method of claim 10 wherein said relaxed SiGe substrate comprises a relaxed SiGe layer and a substrate.

20. The method of claim 19 wherein said substrate is a bulk semiconductor substrate or a substrate including an insulating layer in which said relaxed SiGe layer is formed thereon.
